(19) United States
(12) Patent Application Publication
(10) Pub. No.: US 2025/0379423 A1
(43) Pub. Date: Dec. 11, 2025

(54) ENERGY TRANSFER SYSTEM FOR MOBILE MACHINES

(71) Applicant: Caterpillar Inc., Peoria, IL (US)

(72) Inventors: Rajesh A., Chennai (IN); Richard G. AUCH, Peoria, IL (US); Zachary T. KROEHLER, Peoria, IL (US); Richa PRASAD, Gujarat (IN)

(73) Assignee: Caterpillar Inc., Peoria, IL (US)

(21) Appl. No.: 18/738,606

(22) Filed: Jun. 10, 2024

(51) Int. Cl. H02B 1/56; B60L 5/38; H02H 9/02; H05K 7/20

(52) U.S. Cl. CPC H02B 1/565; B60L 5/38; H05K 7/20136; H02H 9/02

(57) ABSTRACT

An energy transfer system for an electrically powered machine may include a single compartment of the machine. The single compartment of the machine may include an electrical circuit. The electrical circuit may include one or more switches. The one or more switches may be configured to electrically connect and disconnect the energy transfer system from a power source. The electrical circuit may further include a power distribution system. The power distribution system may be configured to accept power from the power source and supply the power to the electrically powered machine. The electrical circuit may still further include an overcurrent protection system. The overcurrent protection system may be configured to prevent an excess flow of current into the electrically powered machine.

### TECHNICAL FIELD

The present disclosure relates generally to an energy transfer system for an electric machine and, more specifically, a housing assembly and energy transfer system for receiving power from electrically conductive lines or rails.

### BACKGROUND

Mobile industrial machines, such as earth-moving machines, can be of substantial weight and can bear immense loads, thus requiring a large amount of power. Many industrial machines are driven by internal combustion engines. However, internal combustion engines have drawbacks such as fuel costs, fuel transport difficulties, and detrimental engine emissions. Accordingly, there has been a movement toward powering large mobile industrial machines with chargeable hybrid or all-electric power systems.

While chargeable hybrid and all-electric power systems for industrial machines are beneficial for alleviating some fuel costs and emission concerns, these systems present challenges. For example, the use of chargeable hybrid or all-electric systems in an industrial capacity requires a significant investment in charging infrastructure, particularly due to the location of industrial worksites. While the use of fixed overhead electricity-conducting lines is one solution for charging or powering vehicles with predetermined routes or terrain (e.g., trains, subways, buses, etc.), overhead lines are not practical for all machines or worksites, such as freely-steerable industrial machines and worksites with uneven terrain. To address these problems, and as an alternative to fixed overhead lines, such industrial machines may use portable rail conductor systems deployed on the ground and accessible by mobile industrial machines having an extendable power conducting arm.

Regardless of the location of the power conducting line or rail, such chargeable hybrid or all-electric mobile industrial machines may utilize an energy transfer system and a power distribution system separately (e.g., as separate electrically connected systems). Use of separate energy transfer and power distribution systems creates duplicative safety systems and reduces system efficiency while increasing cost.

A system for providing electric power to a rail vehicle is described in European Patent App. Pub. No. 4206022A1, published Jul. 5, 2023 (“the '022 publication”). The system described in the '022 publication discloses a system for supplying energy to rail vehicles that can be moved on a track. The system comprises a supply unit for generating and/or converting electrical energy, in particular traction current. The supply unit is designed as a mobile, self-supporting steel structure, as a container. The system further comprises a rail vehicle and a connecting device for transmitting the electrical energy between the supply unit and rail vehicle. However, the reference does not mention whether the system comprises all of the components associated with energy transfer, cooling, and power distribution into a single housing for use with a mobile machine.

Aspects of the present disclosure may solve one or more of the problems set forth above and/or other problems in the art. The scope of the current disclosure, however, is defined by the attached claims, and not by the ability to solve any specific problem.

### SUMMARY

In one aspect, an energy transfer system for an electrically powered machine may include a single compartment of the machine. The single compartment of the machine may include an electrical circuit. The electrical circuit may include one or more switches. The one or more switches may be configured to electrically connect and disconnect the energy transfer system from a power source. The electrical circuit may further include a power distribution system. The power distribution system may be configured to accept power from the power source and supply the power to the electrically powered machine. The electrical circuit may still further include an overcurrent protection system. The overcurrent protection system may be configured to prevent an excess flow of current into the electrically powered machine.

In another aspect, an energy transfer system for an electrically powered machine may include an electrical circuit. The electrical circuit may include one or more switches. The one or more switches may be configured to electrically connect and disconnect the energy transfer system from a power source. The electrical circuit may further include a power distribution system located adjacent the one or more switches. The power distribution system may be configured to accept power from the power source and supply the power to the electrically powered machine. The power distribution system may include an inductor, and an overcurrent protection system configured to prevent an excess flow of current into the electrically powered machine. The electrical circuit may still further include a controller. The controller may be configured to transmit signals to the one or more switches. The one or more switches, power distribution system, overcurrent protection system and controller may all be located in a common cabinet of the powered machine.

In still another aspect, an energy transfer system for an electrically powered machine may include a single cabinet of the electrically powered machine. The single cabinet of the electrically powered machine may include an electrical circuit. The electrical circuit may include one or more switches. The one or more switches may be configured to electrically connect and disconnect the energy transfer system from a power source. The electrical circuit may further include a power distribution system. The power distribution system may be configured to accept power from the power source and supply power to the electrically powered machine. The electrical circuit may further include a surge protection system. The surge protection system may include at least one surge protector or surge arrestor. The electrical circuit may still further include a cooling unit located in the single cabinet for cooling the electrical circuit.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 is a perspective view of an electric mobile machine including a rail connector assembly for coupling with a conductive rail system and an energy transfer system for receiving power from the conductive rail system, according to aspects of the present disclosure.

FIG. 2 is a perspective view of the energy transfer system of FIG. 1.

FIG. 3 is an electrical flow diagram depicting the flow of electricity through the energy transfer system of FIGS. 1 and 2.

FIG. 4 is an air flow diagram depicting the flow of air through the energy transfer system of FIGS. 1 and 2.

### DETAILED DESCRIPTION

Both the foregoing general description and the following detailed description are exemplary and explanatory only and are not restrictive of the features, as claimed. As used herein, the terms “comprises,” “comprising,” “has,” “having,” “includes,” “including,” or other variations thereof, are intended to cover a non-exclusive inclusion such that a process, method, article, or apparatus that comprises a list of elements does not include only those elements, but may include other elements not expressly listed or inherent to such a process, method, article, or apparatus. In this disclosure, unless stated otherwise, relative terms, such as, for example, “about,” “substantially,” and “approximately” are used to indicate a possible variation of +10% in the stated value.

As used herein, the terms “upstream” and “proximal” are intended to locationally identify components, parts, assemblies, and systems located closer to the frame/body of the mobile machine. Conversely, the terms “downstream” or “distal” are intended to locationally identify components, parts, assemblies, and systems located farther away from the frame/body of the mobile machine. In the context of an electrical circuit, “the terms “upstream” and “proximal” are intended to locationally identify components, parts, assemblies, and systems located closer to a source relative to a given component, part, assembly, or system. In the context of an electrical circuit, “the terms “downstream” and “distal” are intended to locationally identify components, parts, assemblies, and systems located further away from a source relative to a given component, part, assembly, or system.

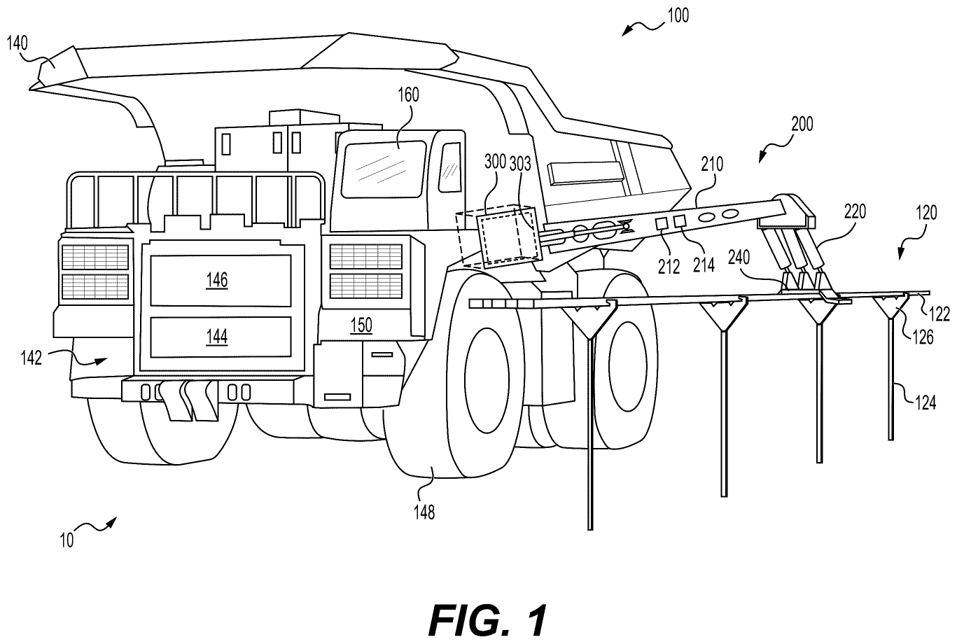

FIG. 1 depicts a mobile machine power system 100 including a mobile machine 140 having an electricity-conducting connector assembly 200, and an electricity-conducting rail system 120 for providing electric power to the mobile machine 140. The mobile machine 140 includes an electric drive system 142 having at least one electric motor 144 and at least one battery system 146. The electric drive system 142 drives a set of ground-engaging elements 148, such as tires or continuous tracks, for propelling and maneuvering the mobile machine 140. The mobile machine 140 also includes a frame/body 150 that supports the mobile machine's mechanical components, including the electricity-conducting connector assembly 200. Mobile machine 140 may include either a hybrid or an all-electric power system, and the electricity-conducting rail system 120 may be applied to either system. The systems, devices, and methods may be applicable to two primary types of hybrid systems: those that receive outside power from an external source (e.g., an internal combustion engine) and those that are self-contained and do not receive external power input. It will be understood by one of ordinary skill in the art that the systems, devices, and methods of the disclosure are applicable to various configurations of off-vehicle electrically conductive surfaces configured to provide power to mobile machine 140. For example, the systems, devices, and methods of the disclosure are also applicable to overhead electrical cables and/or wires. Mobile machine 140 and its various systems may be controlled via a machine operator located in the operator cabin 160, and/or mobile machine 140 may be semi- or fully-autonomous or remotely operated.

The mobile machine 140 is free-steering, allowing the operator of the machine (or autonomous control system) to freely control the direction and route of the machine. Thus, the exemplary mobile machine 140 is configured to travel (e.g., in a free-steering manner) selectively along a work route or path within a job site, with the electricity-conducting rail system 120 positioned generally along the route or path. The mobile machine 140 of FIG. 1 is shown in the context of a mining haul truck which is commonly used for transporting ore in a mine environment. The present disclosure is not so limited, however, and other types of machines are within the scope of the present disclosure, including, for example, load-haul-dump machines, articulated trucks, excavators, underground mining dump loaders and trucks, wheel loaders, wheel tractor-scrapers, or other machines. It will be further understood that the systems, devices, and methods of the disclosure may also be applicable to consumer electric vehicles and machines, as well as electrically powered semi-trailers and the like.

The electricity-conducting rail system 120 includes a plurality of elevated conductor rails 122 connected to a power source (e.g., a power grid, generator, and/or energy storage devices, not shown). The conductor rails 122 may be supported by a plurality of ground-engaging support poles 124 and rail bracket assemblies 126. While FIG. 1 shows an example where the plurality of conductor rails 122 contains three conductor rails, the plurality of conductor rails 122 may contain fewer or more rails. In this example, two of the conductor rails provide electrical power at different polarities (e.g., a conductor rail with a positive polarity and a conductor rail with a negative polarity) while the third conductor rail provides a reference of 0 volts (ground). The elevated conductor rails 122 may have a height, for example, in the range of 8 to 15 feet above the ground 10. Thus, the electricity-conducting rail system does not form a pantograph-type overhead power system, nor an under-machine or low-ground-located power system. It will be appreciated by one of ordinary skill in the art that the power distribution system of this disclosure is capable of accepting power from a pantograph-type overhead power system and under-machine or low-ground-located power distribution systems.

The electricity-conducting connector assembly 200 electrically connects the mobile machine 140 to the electricity-conducting rail system 120. The electricity-conducting connector assembly 200 includes a boom assembly 210 having a proximal end and a distal end; an arm assembly, such as a trailing arm assembly 220 having a proximal end connected to the distal end of the boom assembly 210; and a contactor assembly 240 connected to a distal end of the trailing arm assembly 220. As used herein, the term “trailing” refers to a direction opposite the forward direction of travel of the mobile machine 140. The boom assembly 210 may house, for example, a hydraulic system 212 for pivotably extending, retracting, and locking the boom assembly 210, and a pneumatic system 214 for generating and controlling fluid pressure of downstream components (e.g. the trailing arm assembly 220 and the contactor assembly 240), and an integrated busbar for transferring electrical energy along a length of the boom assembly 210. While the disclosure mentions a pneumatic system 214, it is understood that the pneumatic system 214 could alternatively be a hydraulic system.

As shown in FIG. 1 the boom assembly 210 extends generally horizontally from a side of the mobile machine and is connected to a side of the frame/body 150 of the mobile machine 140 about a pivot joint. The pivot joint is located at a height of over 8 feet on the machine (above the ground 10). As previously referenced, the electricity-conducting connector assembly 200 includes several different states of deployment, including an extended state in which the boom assembly 210 is extended generally horizontally outward away from a side of the mobile machine 140 (as shown in FIG. 1), a retracted state (not shown) in which the boom assembly 210 is rotated or pivoted inward to rest against the frame/body 150 of the mobile machine (not shown), and a locked state in which the boom assembly is locked to the side of the machine frame/body 150 in the retracted state by a hydraulically-actuated locking pin (not shown). Finally, while the boom assembly 210 is shown to be attached to a mining haul truck, the same boom assembly 210 is capable of being incorporated in various types of mobile machines 140 by use of an interchangeable adapter (not shown) that is specific to the type of machine being operated.

The trailing arm assembly 220 forms a mechanical and electrical connection between boom assembly 210 and contactor assembly 240, and may include one or more arms. The one or more arms may be extendable and retractable and may have multiple degrees of freedom to allow for vertical and lateral pivoting about the boom assembly 210. In one arrangement, trailing arm assembly 220 may form a double parallel bar linkage including three telescoping arms that are configured to create a current path when in a fully-extended condition.

The current path created by electricity-conducting connector assembly 200 when in the fully extended condition may supply power to the mobile machine 140. As discussed above, mobile machine 140 may be a hybrid system (e.g., featuring an internal combustion engine and a battery system) or may be a fully electric system (e.g., exclusively battery powered). The systems, devices, and methods of the disclosure may also be applicable to electrically powered machines without batteries (e.g., machines that derive power for locomotion entirely from energy received electricity-conducting rail system 120). Such configurations may be desirable in locations with increased fire hazard, such as an underground mine where a battery fire may be difficult to contain.

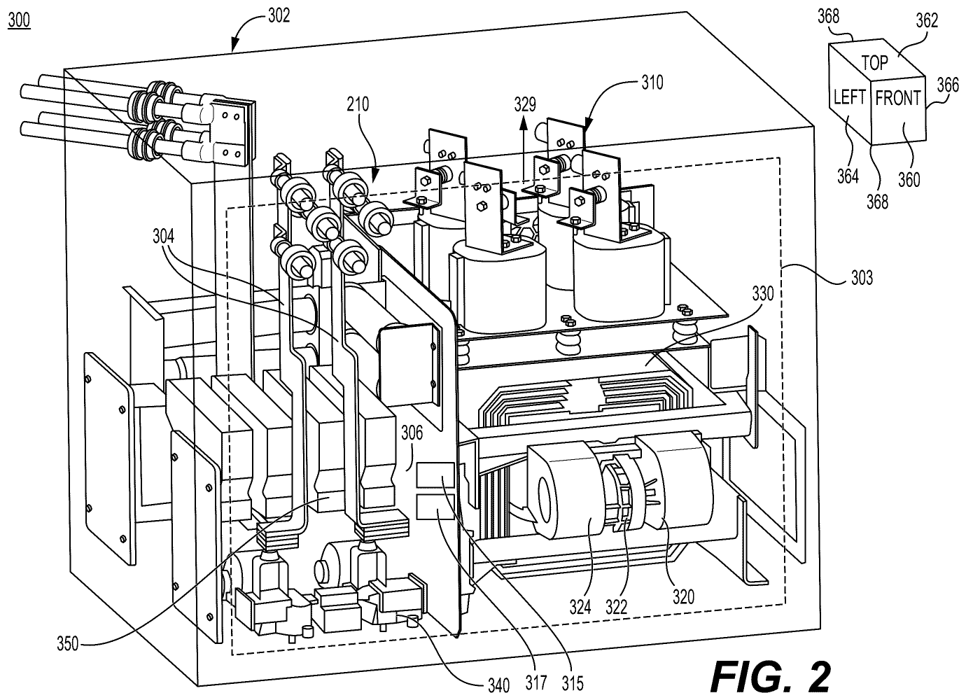

Before the current path reaches the electrical subsystems of mobile machine 140, power is received by energy transfer system 300. Energy transfer system 300 is discussed in greater detail with respect to FIG. 2. Energy transfer system 300 is depicted in FIG. 1 as being located distally (e.g., directly behind) of electricity-conducting connector assembly 200, though this is only exemplary. Energy transfer system 300 may be located in various locations in and/or on mobile machine 140. For example, energy transfer system 300 may be positioned behind battery system 146. One of ordinary skill in the art will appreciate that the location of energy transfer system 300 may also vary based on the type of machine and use case of the machine.

FIG. 2 is a perspective view of the energy transfer system 300 of FIG. 1. Energy transfer system 300 may include various subsystems configured to distribute power, protect against overcurrents, protect against power surges and lightning strikes, and provide noise filtration. Energy transfer system 300 may combine the features and functionality of energy transfer systems and power distribution systems into a single integrated assembly configured for a variety of machines. Energy transfer system 300 may receive power from a plurality of conductor rails 122 via boom assembly 210. It will be appreciated that the various subsystems of energy transfer system 300 may be electrically, operatively, and/or communicatively coupled to one another in various combinations. The orientation cube provided in the upper corner of FIG. 2 corresponds to faces of energy transfer system 300. The various orientations corresponding to faces of energy transfer system 300 may also be referred to as portions or sides (e.g., a front portion or front side, a left portion or left side, etc.) The bottom portion, or bottom side, is opposite the top portion, or top side and is labeled 368. The front side may also be referred to as front portion 360, the left side may be referred to as left portion 364, the right side may be referred to as right portion 366, the top side may be referred to as top portion 362, and the back side may be referred to back portion 368. Energy transfer system 300 may be positioned or disposed to form an outer surface portion of mobile machine 140 (e.g., as shown in FIG. 1) such that it is accessible for service by an operator or service technician. Throughout this disclosure, reference to orientations (e.g., front, back, top, bottom, right, left) is with respect to a housing or cabinet 302 of energy transfer system 300. Any portion of any face of housing 302 may be configured with a service entrance to provide access to the components of energy transfer system 300. For example, in the exemplary location shown in FIG. 2, a front service panel or entrance may form an outer surface of a side of mobile machine 140.

Energy transfer system 300 may include a central vertical partition 306. Central vertical partition 306 may be a generally solid wall as shown, or a supporting framework with openings. Energy distribution system 310 may be on one side of central vertical partition 306 and disconnecting devices 350 may be on a different, opposite side of central vertical partition 306.

As noted above, energy transfer system 300 may include a housing 302. Housing 302 may also be referred to as a cabinet. Housing or cabinet 302 may enclose (in a single area) energy transfer system 300. Housing or cabinet 302 may have faces corresponding to the orientations described above of the orientation cube. Housing or cabinet 302 may include a plurality of service panels disposed on the faces of housing or cabinet 302 (not shown in FIG. 2). For example, a service panel or entrance 303 on the front face of housing or cabinet 302 may form a portion of an outer surface of the machine 100 and may allow an operator easy access to cooling unit 320. One of ordinary skill in the art will appreciate that the location and geometry of housing or cabinet 302 may be adapted to the specific type of mobile machine 140 that the housing or cabinet 302 is to be attached to. Entrance 303 may also include an interface for voltage measurement via an instrument that an operator may use before servicing energy transfer system 300.

Energy transfer system 300 may include an energy distribution system 310. Energy distribution system 310 may include various fuses, circuits, bus bars, and sensors (e.g., voltage and current sensors) configured to route energy throughout energy transfer system 300 and/or mobile machine 140. Energy distribution system 310 may be positioned near top portion 362 of housing 302. Energy distribution system 310 may include a controller 315 that may monitor voltages and/or currents reported by the voltage and/or current sensors, monitor one or more temperature sensors 317 of energy transfer system 300, adjust an air intake speed to adjust cooling rates, and may provide fault monitoring functionality. Controller 315 may perform isolation monitoring (e.g., via an active isolation monitoring system) resistance measurements to determine the isolation of high voltage systems from low voltage systems of energy transfer system 300. Current and voltage sensors may determine that a predetermined amount of current or voltage has been exceeded, respectively. Controller 315 may detect voltages and provide communications and signaling to a service person through various illuminated hazard lamps (not shown in FIG. 2) located in the housing or cabinet 302.

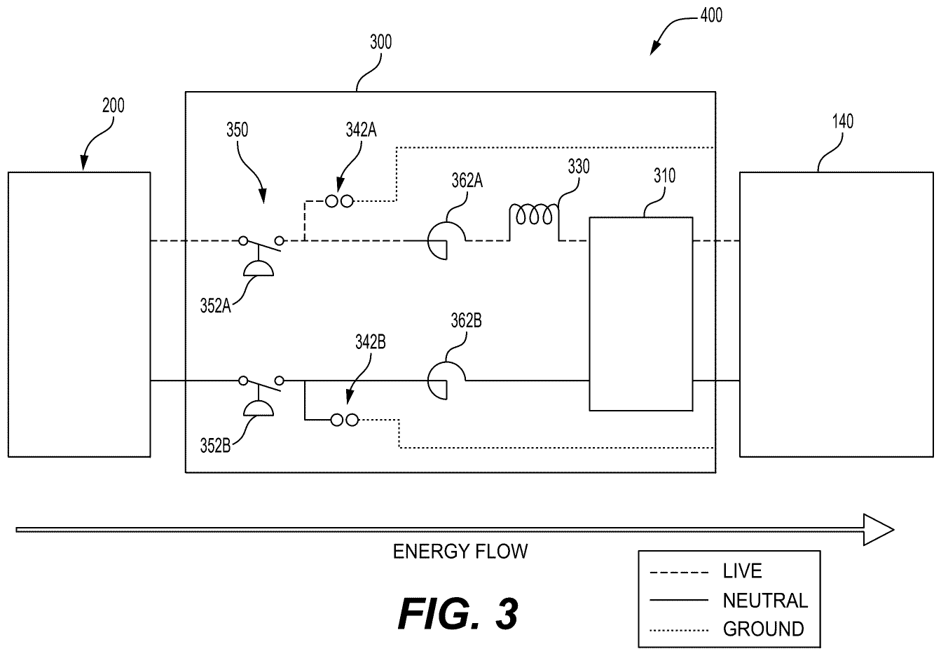

Controller 315 controls various electrical components of energy transfer system 300 such as switch disconnects 352A and 352B (FIG. 3). For example, controller 315 may transmit signals to switch disconnects 352A and 352B to connect or break various electrical connections. Controller 315 may include a processor and firmware, network connectivity (for example, a 5G and/or satellite connection, and various contemplated future networking implementations such as 6G), and various components used to identify the type of power connection that is connected to mobile machine 140 (e.g., an overhead line or electrical rail). Controller 315 may communicate with a charger (e.g., electricity-conducting connector assembly 200) connected to mobile machine 140, with battery system 146, electric drive system 142, electric motor 144, and with the electrical systems of energy transfer system 300 to coordinate charging output of energy transfer system 300 with charging requirements of mobile machine 140. Controller 315 may communicate (via its network connectivity) charge states of mobile machine 140 (e.g., state of charge of battery system 146), a status of one or more surge arrestors, a status of one or more surge protectors, a measurement and/or detection indication of a ground fault, a total cost of electricity used for charging, a total greenhouse gas footprint associated with a current charging operation or a cumulative sum of charging operations, start and stop times of charging, temperature, battery health of mobile machine 140, and a current input power and voltage of a connected charger. For example, an off-site operator may query controller 315 to determine a current charge state of mobile machine 140. Controller 315 may be a single component, or one or more components communicatively and/or operatively linked to one another.

Controller 315 monitors various physical states of energy transfer system 300. For example, controller 315 may monitor internal temperatures of energy transfer system 300 via one or more communicatively coupled temperature sensors (e.g., temperature sensor 317). Controller 315 may adjust or modify a speed of an air intake (e.g., controlling a cooling fan speed) 320 based on the detected thermal conditions (e.g., a sensor reading) to exhaust heat from energy transfer system 300 in accord with a predefined fan curve. The predefined fan curve defines a relationship between detected temperatures and fan speed.

Energy transfer system 300 may include an input bus bar assembly 304. Bus bar assembly 304 may extend from housing 302 and may be directly connected to boom assembly 210. Energy transfer system 300 may also include one or more disconnecting devices 350. Disconnecting devices 350 may serve as a safety feature to electrically isolate the rest of energy transfer system 300 from incoming power via boom assembly 210. Disconnecting devices 350 may be one or more switches configured to accept signaling from controller 315. One of ordinary skill in the art will recognize that disconnecting devices 350 may serve as an additional means of electrically disconnecting mobile machine 140 from plurality of conductor rails 122 in addition to moving boom assembly 210 away from (e.g., breaking the circuit with) a plurality of conductor rails 122 via hydraulic system 212. Disconnecting devices 350 may be electrically upstream of the other various electrical subsystems of energy transfer system 300 such that when disconnecting devices 350 have disconnected the circuit, the other electrical systems of energy transfer system 300 may not receive power from conductor rails 122. Disconnecting device 350 may be located in various quantities and at various locations around one or more circuits of energy transfer system 300. Further discussion of disconnecting devices 350 is provided with respect to FIG. 3.

Energy transfer system 300 may include an inductor 330. While a single inductor 330 is described in FIGS. 2-3, it will be appreciated that other quantities of inductors may be utilized with the systems, devices, and methods of the disclosure. Inductor 330 may resist changes in current supplied by boom assembly 210 and thus may smooth the supply of current to the other electrical systems of energy transfer system 300.

Energy transfer system 300 may include surge devices 340. Surge devices 340 may include both surge protectors and surge arrestors. Surge devices 340 may be positioned on an opposite side of central vertical partition 306 as compared to energy distribution system 310. Surge device 340 may be positioned below disconnecting devices 350. Surge protectors may be electrically coupled to secondary electric circuits to protect sensitive electronics, such as controller 315, from voltage spikes. Surge protectors may accept incoming electricity directly and may pass the electricity to other components downstream of the surge protectors. Surge protectors may be metal oxide varistors configured to divert excess voltage to one or more grounding elements of energy transfer system 300, such as grounding busbars. Surge arrestors may be electrically coupled to primary electric circuits (e.g., circuits configured to accept electricity needed to directly charge or power mobile machine 140). Surge arrestors may provide a low-resistance ground path (e.g., to grounding busbars), thereby allowing excess energy such as from a lightning strike to be safely dissipated.

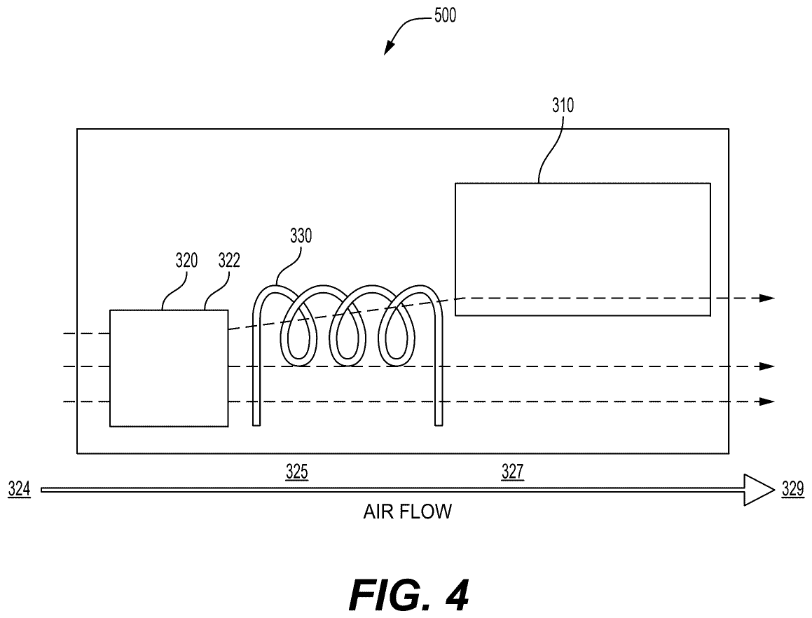

Energy transfer system 300 may include an cooling unit 320. Cooling unit 320 may comprise a blower, fan, or turbine configured to draw in and circulate cooling air through energy transfer system 300. Cooling unit 320 may be positioned on the same side of central vertical partition 306 as energy distribution system 310. Cooling unit 320 may be positioned adjacent to an outer surface machine 140. Air circulation through energy transfer system 300 may remove heat from components of energy transfer system 300 that generate heat and conduct heat. Cooling unit 320 may supply cooling air to various systems of energy transfer system 300, such as surge protectors 342A and 342B, power distribution system 310, and inductor 330. Cooling unit 320 may cause cooler outside air to flow into, through, and out of energy transfer system 300. Cooling unit 320 may draw in outside air through a filter 322. Cooling unit 320 may be positioned on front portion 360 and may exhaust air out of back portion 368. Filter 322 may prevent foreign particulate matter such as dust and sand from entering energy transfer system 300 while cooling unit 320 is active. Filter 322 may enhance the cooling properties of cooling unit 320 by preventing buildup of contaminants on internal surfaces of energy transfer system 300. Air may enter energy transfer system 300 at air flow position 324, and may exit energy transfer system 300 at air flow position 329. Further description of air flow through energy transfer system 300 is provided with respect to FIG. 4. Controller 315 may detect the status of filter 322 and communicate with mobile machine 140 for servicing or cleaning.

### INDUSTRIAL APPLICABILITY

The disclosed aspects of the energy transfer system above can be used for receiving power from an electricity-conducting rail system, the contactor assembly sliding along the electricity-conducting rail system for charging a free-steering mobile machine while operating on a worksite, and the contactor assembly disengaging from the electricity-conducting rail system. Energy transfer system 300 may consolidate the functionality of multiple systems into a single system (e.g., power distribution and energy transfer). Energy transfer system 300 may improve serviceability compared to existing systems by being located on an outer surface portion of mobile machine 140. Energy transfer system 300 may increase the safety of mobile machine via surge protectors (e.g., surge protectors 342A and 342B). Energy transfer system 300 may also offer reduced material use compared to existing systems by consolidating the functionality of energy transfer and power distribution into a single integrated system.

FIG. 3 shows an electrical circuit diagram 400 depicting the flow of electricity through the energy transfer system of FIGS. 1 and 2. Flow diagram 400 may represent a simplified representation of how electricity flows from (source) electricity-conducting connector assembly 200, through energy transfer system 300, and to (load) mobile machine 140 (e.g., a power converter, traction power systems, and/or battery systems). It will be understood by one of ordinary skill in the art that electricity flows from left to right in the exemplary electrical circuit diagram 400. One of ordinary skill in the art will recognize that the dashed lines of the electrical circuit diagram 400 may indicate a live line carrying voltage, the solid lines may indicate a neutral line for returning current to the source (e.g., power conducting assembly 200), and that the dotted lines may indicate a ground line. It should be noted that the circuit of electrical circuit diagram 400 may be connected to one or more various electrical circuits and/or components not shown in FIG. 3.

Electricity may first flow from power conducting assembly 200 to switch disconnect 352A. As discussed above, switch disconnect 352A may be configured to accept signaling from controller 315 to connect or break the electrical circuit. In the connected position, electricity may flow through switch disconnect 352A. In the event of a current surge, such as from a lightning strike, electricity may be routed through surge protection 342A (e.g., a surge protector and/or surge arrestor) to a ground portion of the circuit. Under typical operations, electricity may flow from switch disconnect to a power filter 362A. Power filter 362A may be configured to eliminate or reduce noise, harmonics, and various electrical abnormalities and disturbances from the source (e.g., power conducting assembly 200). Filtering may reduce electromagnetic interference and radio frequency interference to downstream electronics (e.g., mobile machine 140) and may improve the reliability and/or performance of electronics downstream of power filter 362A.

Electricity may flow through power filter 362A to inductor 330. Inductor 330 may further improve the quality of the current flow by resisting changes in current supplied by power conducting assembly 200. Inductor 330 may also reduce inrush currents to mobile machine 140 during initial startup operations.

After flowing through inductor 330, electricity may continue into power distribution system 310. Power distribution system 310 may include one or more fuses, one or more busbars, and one or more electrical sensors (e.g., current and/or voltage sensors). Power distribution system 310 may include one or more connections to controller 315. Power distribution system 310 may be configured to accept signaling and/or instructions from controller 315 to control and/or monitor one or more subsystems or components of power distribution system 310. Power distribution system 310 may be electrically, operably, and/or communicatively coupled to mobile machine 140.

Electricity may continue from power distribution system 310 to mobile machine 140. Electricity may flow into a power converter (e.g., a component capable of converting incoming power from a first voltage to a second voltage), traction power systems (e.g., electric drive system 142), and/or battery system 146.

The electric circuit of electric circuit diagram 400 may include a return path to power conducting assembly 200 via a neutral line. Controller 315 may detect a current imbalance on the return path via the one or more voltage and/or current sensors. Electricity may flow from mobile machine 140 to power distribution system 310. Electricity may continue to a power filter 362B, which may perform substantially similar functions as power filter 362A described above. In the event of a power surge on the neutral portion of the circuit, electricity may be routed to a surge protection 342B (e.g., a surge protector and/or surge arrestor) to a ground portion of the circuit. Under normal operating conditions, electricity may then flow into switch disconnect 352B, which may perform substantially similar functions to switch disconnect 352A. Electricity may then flow back to conducting assembly 200, thereby completing the electric circuit.

FIG. 4 is an air flow diagram 500 depicting the flow of air through the energy transfer system 300 of FIGS. 1 and 2. Air may be passed through energy transfer system 300 to cool various systems and components of energy transfer system 300. Air may begin at air flow position 324. Air flow diagram 500 is described sequentially, that is, air from intake 320 may contact components in the order that they are described below. Air flow diagram 500 may begin at air flow position 324. Air flow position 324 may be understood as the initial intake position of outside air (e.g., air from outside of energy transfer system 300). Air flow position 324 may be located at front portion 360. Air located at air flow position 324 may be drawn in to energy transfer system 300 through filter 322 via suction created by cooling unit 320. As described above, air passing through filter 322 may be scrubbed of particulate matter. After passing through filter 322, air may be located at air flow position 325.

Air may flow from air flow position 325 to air flow position 327. Air flow position 327 may correspond to a position approximately behind (e.g., towards back portion 368) inductor 330. One of ordinary skill in the art will recognize that cooling of inductor 330 may offer several benefits, including decreased electrical resistance and increased inductance (e.g., via increased magnetic field strength of inductor 330), and decreased mechanical stress via thermal expansion and contraction.

Air may flow from air flow position 327 to air flow position 329. Air flow position 329 may be located outside energy transfer system 300 and/or mobile machine 140. Air may pass over (and behind) power distribution system 310, including fuses, bus bars and electrical sensors of power distribution system 310. Cooling of busbars may increase the conductivity of the busbars. Increased conductivity of busbars may increase the capability of the busbars to dissipate excess charge from energy transfer system 300. Thus cooling of the busbar(s) may further enhance the safety of energy transfer system 300. Air may pass through an outlet (not illustrated in FIG. 2) positioned on a back portion of energy transfer system 300.

In accordance with the present disclosure, an energy transfer system for a mobile machine allows for external power sources such as a conducting rail to safely and more efficiently charge and/or power a mobile machine. The energy transfer system of the present disclosure may be retrofit to existing mobile machines, or may be utilized with newly designed mobile machines. The energy transfer system of the disclosure may enhance serviceability and safety and may reduce material use in the manufacture of energy transfer systems for mobile machines.

It will be apparent to those skilled in the art that various modifications and variations can be made to the disclosed system without departing from the scope of the disclosure. Other embodiments of the system will be apparent to those skilled in the art from consideration of the specification and practice of the system disclosed herein. It is intended that the specification and examples be considered as exemplary only, with a true scope of the disclosure being indicated by the following claims and their equivalents.

What is claimed is:

1. An energy transfer system for an electrically powered machine, comprising:
a single compartment of the machine, including:
an electrical circuit including:
one or more switches configured to electrically connect and disconnect the energy transfer system from a power source;
a power distribution system configured to accept power from the power source and supply the power to the electrically powered machine; and
an overcurrent protection system configured to prevent an excess flow of current into the electrically powered machine.

2. The energy transfer system of claim 1, further including a blower configured to supply cooling air to both the overcurrent protection system and the power distribution system.

3. The energy transfer system of claim 2, wherein the blower is further configured to supply cooling air across an inductor within the single compartment.

4. The energy transfer system of claim 3, wherein the blower is positioned adjacent an outer surface of the machine.

5. The energy transfer system of claim 1, further including a bus bar extending from the single compartment and directly connected to an electricity-conducting connector assembly extending away from the machine for connecting to a power supply.

6. The energy transfer system of claim 1, wherein the single compartment forms a cabinet having a common service entrance.

7. The energy transfer system of claim 1, wherein the common service entrance forms an outer surface portion of the machine.

8. The energy transfer system of claim 1, further including a central vertical partition, and the energy distribution system is located on a first side of the partition and the one or more switches are located on a second, opposite side of the partition.

9. The energy transfer system of claim 8, wherein the energy distribution system is located at a top portion of the single compartment.

10. The energy transfer system of claim 8, further including a blower located on the first side of the partition.

11. The energy transfer system of claim 10, further including surge protection devices located on the second side of the partition.

12. The energy transfer system of claim 10, wherein the surge protection devices are located below the one or more switches.

13. An energy transfer system for an electrically powered machine, comprising:
an electrical circuit including:
one or more switches configured to electrically connect and disconnect the energy transfer system from a power source;
a power distribution system located adjacent the one or more switches and configured to accept power from the power source and supply the power to the electrically powered machine, the power distribution system including
an inductor, and
an overcurrent protection system configured to prevent an excess flow of current into the electrically powered machine; and
a controller configured to transmit signals to the one or more switches;
wherein the one or more switches, power distribution system, overcurrent protection system and controller are all located in a common cabinet of the powered machine.

14. The energy transfer system of claim 13, wherein the cabinet includes a partition, and the energy distribution system is located on a first side of the partition and the one or more switches are located on a second, opposite side of the partition.

15. The energy transfer system of claim 14, wherein the energy distribution system is located at a top portion of the single compartment.

16. The energy transfer system of claim 15, further including a blower located on the first side of the partition.

17. The energy transfer system of claim 16, further including surge protection devices located on the second side of the partition.

18. The energy transfer system of claim 13, further including a blower configured to supply cooling air across portions of both the overcurrent protection system and the power distribution system.

19. The energy transfer system of claim 13, wherein the electrical circuit further includes a voltage sensor, a power filter, a grounding portion, a temperature sensor, a current sensor, a ground fault detection, and an isolation monitoring system, all located in the common cabinet.

20. An energy transfer system for an electrically powered machine, comprising:
a single cabinet of the electrically powered machine, including:
an electrical circuit including:
one or more switches configured to electrically connect and disconnect the energy transfer system from a power source;
a power distribution system configured to accept power from the power source and supply power to the electrically powered machine;
a surge protection system including at least one surge protector or surge arrestor; and
a cooling unit located in the single cabinet for cooling the electrical circuit.
